(19) United States
(12) Patent Application Publication
(10) Pub. No.: US 2010/0171689 A1
(43) Pub. Date: Jul. 8, 2010

(54) Shift register and organic light emitting display device using the same

(76) Inventor: SeonI Jeong, Yongin-city (KR)

Correspondence Address: LEE & MORSE, P.C., 3141 FAIRVIEW PARK DRIVE, SUITE 500, FALLS CHURCH, VA, 22042, US

(21) Appl. No.: 12/591,290

(22) Filed: Nov. 16, 2009

(30) Foreign Application Priority Data
Jan. 6, 2009 (KR) 10-2009-0000739

(51) Int. Cl. G09G 3/36; G11C 19/00

(52) U.S. Cl. 345/100; 377/79

(57) ABSTRACT

A shift register has a plurality of stages driven by first, second, and third clock signals. Each stage includes a first transistor coupled between a first power source and an output node, and having a gate electrode coupled to a first node, a second transistor coupled between the output node and the third input line, and having a gate electrode coupled to a second node, a third transistor coupled between the first power source and the first node, and having a gate electrode coupled to an input terminal receiving the start pulse or an output signal of a previous stage, a fourth transistor coupled between the first node and a second power source, and having a gate electrode coupled to the first input line, and a fifth transistor coupled between the input terminal and the second node, and having a gate electrode coupled to the second input line.

### BACKGROUND

1. Technical Field

Embodiments relate to a shift register and an organic light emitting display device using the same, and more particularly, to a shift register provided in a driving circuit driving pixel lines and an organic light emitting display device using the same.

2. Discussion of the Related Art

An organic light emitting display device has an array of pixels arranged in a matrix form at intersection areas of data and scan lines. The array of pixels is driven by a scan driving unit supplying scan signals to the scan lines and a data driving unit supplying data signals to the data lines.

The scan driving unit is provided with a shift register that sequentially outputs scan signals to the scan lines so as to select pixels to receive a data signal supplied for each line in the pixel array. The shift register includes multiple stages, each stage having a plurality of transistors.

However, when leakage current caused by off-current of a transistor or the like occurs in the shift register, the output of the shift register may be unstable. Therefore, techniques for minimizing the leakage current generated in the shift register are desired.

### SUMMARY OF THE INVENTION

Embodiments are therefore directed to a shift register and an organic light emitting display device using the same, which substantially overcome one or more of the problems associated with the related art.

It is therefore a feature of an embodiment to provide a shift register capable of minimizing leakage current and an organic light emitting display device using the same.

It is therefore another feature of an embodiment to provide a shift register having a simple structure configured using a relatively small number of devices and an organic light emitting display using the same.

It is therefore yet another feature of an embodiment to provide a shift register having stabilized output characteristics devices and an organic light emitting display using the same.

At least one of the above and other features and advantages may be realized by providing a shift register having a plurality of stages dependently coupled to an input line of a start pulse, the shift register being driven by first, second, and third clock signals respectively supplied from first, second, and third input lines. In the shift register, each stage includes a first transistor coupled between a first power source and an output node, the first transistor having a gate electrode coupled to a first node, a second transistor coupled between the output node and the third input line, the second transistor having a gate electrode coupled to a second node, a third transistor coupled between the first power source and the first node, the third transistor having a gate electrode coupled to an input terminal to which the start pulse or an output signal of a previous stage is input, a fourth transistor coupled between the first node and a second power source, the fourth transistor having a gate electrode coupled to the first input line, and a fifth transistor coupled between the input terminal and the second node, the fifth transistor having a gate electrode coupled to the second input line.

At least one of the above and other features and advantages may be realized by providing an organic light emitting display device including a pixel unit having a plurality of pixels positioned at intersection portions of scan and data lines, a scan driving unit having a shift register sequentially applying scan signals to the scan lines, and a data driving unit applying data signals to the data lines. In the organic light emitting display device, the shift register has a plurality of stages dependently coupled to an input line of a start pulse and is driven by first, second and third clock signals respectively supplied from first, second and third input lines. In the shift register, each stage includes a first transistor coupled between a first power source and an output node, the first transistor having a gate electrode coupled to a first node, a second transistor coupled between the output node and the third input line, the second transistor having a gate electrode coupled to a second node, a third transistor coupled between the first power source and the first node, the third transistor having a gate electrode coupled to an input terminal to which the start pulse or an output signal of a previous stage is input, a fourth transistor coupled between the first node and a second power source, the fourth transistor having a gate electrode coupled to the first input line, and a fifth transistor coupled between the input terminal and the second node, the fifth transistor having a gate electrode coupled to the second input line.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a block diagram of an organic light emitting display device according to an embodiment;

FIG. 2 illustrates a block diagram of an example of a shift register included in a scan driving unit of FIG. 1;

FIG. 3 illustrates a detailed circuit diagram of an example of an arbitrary stage shown in FIG. 2; and

FIG. 4 illustrates a waveform diagram of input/output signals of the stage shown in FIG. 3.

### DETAILED DESCRIPTION

Korean Patent Application No. 10-2009-0000739, filed on Jan. 6, 2009, in the Korean Intellectual Property Office, and entitled: “Shift Register and Organic Light Emitting Display Device Using the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of embodiments to those skilled in the art.

Here, when a first element is described as being coupled to a second element, the first element may be not only directly coupled to the second element but may also be indirectly coupled to the second element via a third element. Further, some of the elements that are not essential to the complete understanding of embodiments may be omitted for clarity. Also, like reference numerals refer to like elements throughout.

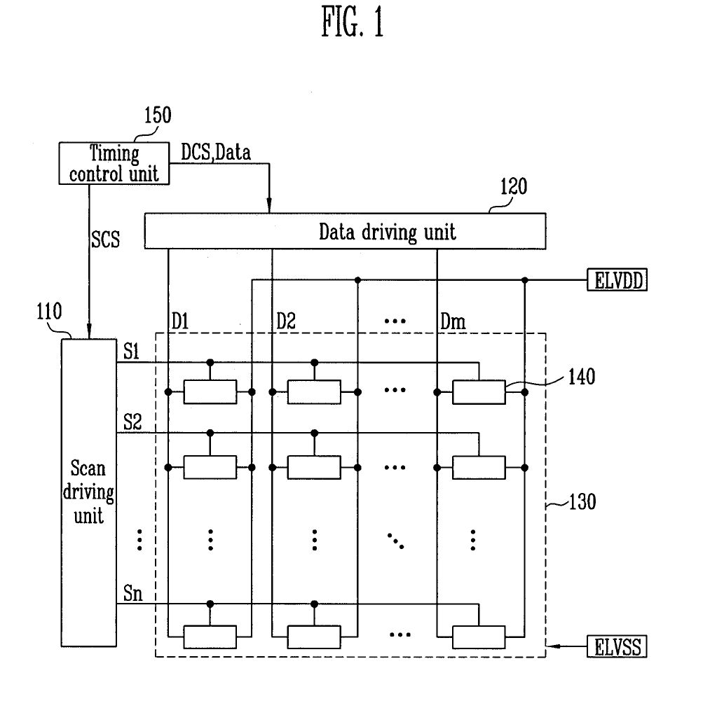

FIG. 1 illustrates a block diagram of an organic light emitting display device according to an embodiment of the present invention. Referring to FIG. 1, the organic light emitting display device may include a pixel unit 130 having pixels 140 formed in portions partitioned by scan lines S1 to Sn and data lines D1 to Dm, a scan driving unit 110 driving the scan lines Si to Sn, a data driving unit 120 driving the data lines D1 to Dm, and a timing control unit 150 controlling the scan driving unit 110 and the data driving unit 120. The pixels 140 may include organic light emitting diodes.

The scan driving unit 110 may receive a scan driving control signal SCS supplied from the timing control unit 150, generate scan signals, and supply the generated scan signals to the scan lines S1 to Sn. Here, the scan driving control signal SCS may include a start pulse SP, clock signals CLK, and the like.

To this end, the scan driving unit 110 may include a shift register that sequentially generates scan signals in response to the start pulse SP and the clock signals CLK, and applies the scan signals to the scan lines S1 to Sn.

The data driving unit 120 may receive a data driving control signal DCS and a data Data supplied from the timing control unit 150, and may generate data signals. The data signals generated from the data driving unit 120 may be supplied to the data lines D1 to Dm.

The timing control unit 150 may generate the scan driving control signal SCS and the data driving control signal DCS in response to synchronization signals supplied from the outside thereof. The scan driving control signal SCS generated from the timing control unit 150 may be supplied to the scan driving unit 110. The data driving control signal DSC generated from the timing control unit 150 may be supplied to the data driving unit 120. The timing control unit 150 may supply a data Data supplied from the outside to the data driving unit 120.

The pixel unit 130 may include a plurality of pixels 140 positioned at intersection portions of the scan lines S1 to Sn and the data lines D1 to Dm. Each of the pixels 140 may receive first and second pixel voltages ELVDD and ELVSS supplied from the outside thereof, and may receive scan and data signals respectively supplied from the scan and data driving units 110 and 120. Each of the pixels 140, which receives the first and second pixel voltages ELVDD and ELVSS, and the scan and data signals, may be selected by a scan signal to receive a data signal and may generate light corresponding to the data signal.

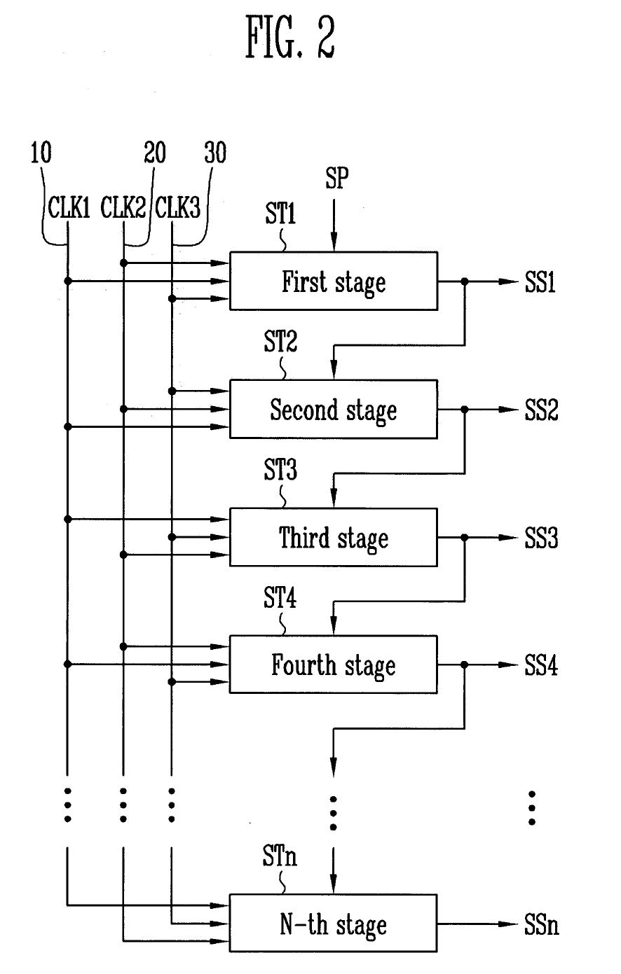

FIG. 2 illustrates a block diagram showing an example of a shift register included in the scan driving unit 110 of FIG. 1. Referring to FIG. 2, the shift register may include a plurality of stages ST1 to STn dependently coupled to an input line of a start pulse SP. Here, the respective stages ST1 to STn may be driven by first, second and third clock signals CLK1, CLK2, and CLK3 respectively input from the first, second, and third input lines 10, 20, and 30, and supplied so that their phases are sequentially delayed.

The first stage ST1 may allow a start pulse SP supplied thereto to be phase-delayed by one clock in response to the first to third clock signals CLK1 to CLK3 and may output the phase-delayed start pulse SP. Each i-th stage of the second to n-th stages ST2 to STn may allow an output signal SS of an immediately previous stage STi-1, supplied thereto, to be phase-delayed by one clock and may output the phase-delayed output signal SSi in response to the first to third clock signals CLK1 to CLK3.

Through the driving described above, the respective stages ST1 to STn may generate sequentially phase-delayed output signals SS1 to SSn, and may sequentially supply the output signals SS1 to SSn to the respective scan lines.

While the shift register illustrated in FIG. 2 is driven by three sequentially phase-delayed three clock signals CLK1 to CLK 3, the shift register may be practically driven by other numbers, e.g., four, of sequentially phase-delayed clock signals.

When four clock signals are used, each of the stages STi may receive only three of the four clock signals to generate an output signal SSi in response to the three clock signals. For example, the first stage ST1 may receive first, third, and fourth clock signals, and the second stage ST2 may receive second, fourth, and first clock signals respectively obtained by allowing the first, third and fourth clock signals to be sequentially phase-delayed by one clock. Each of the third to n-th stages ST3 to STn may receive three clock signals sequentially phase-delayed by one clock in the same manner.

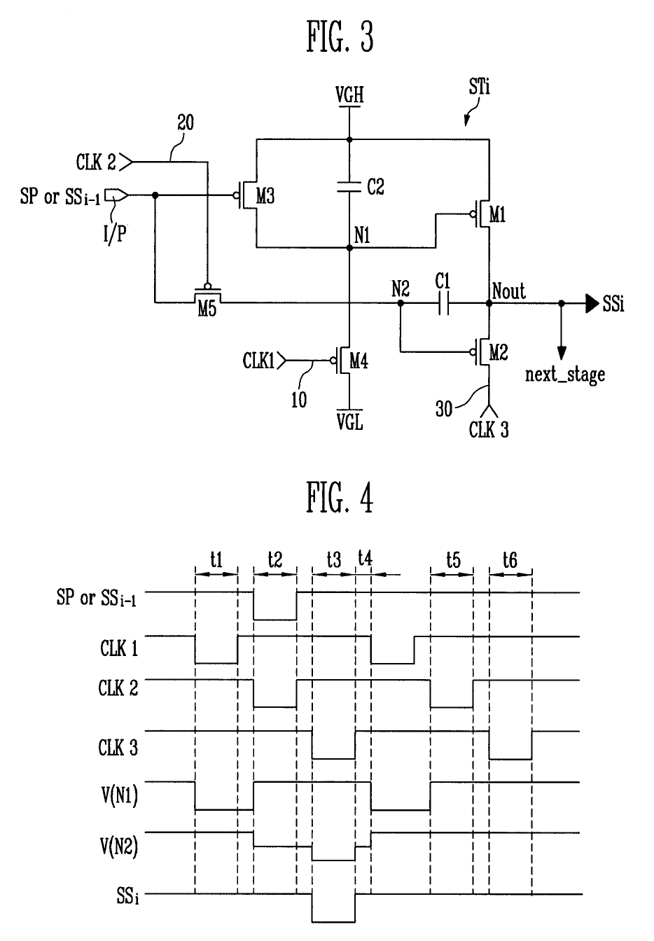

FIG. 3 illustrates a detailed circuit diagram of an example of an arbitrary stage shown in FIG. 2. Referring to FIG. 3, the arbitrary stage STi may include first to fifth transistors M1 to M5 and first and second capacitors C1 and C2.

The first transistor M1 may be coupled between an output node Nout and a first power source VGH, e.g., a gate high-level voltage source. A gate electrode of the first transistor M1 may be coupled to a first node N1. When the voltage level at the first node N1 is a low level, the first transistor M1 may be turned on to allow the first power source VGH to be electrically coupled to the output node Nout. That is, when the first transistor M1 is turned on, a high-level scan signal SSi may be output to the output node Nout.

The second transistor M2 may be coupled between the output node Nout and the input line 30. A gate electrode of the second transistor M2 may be coupled to a second node N2. When the voltage level at the second node N2 is a low level, the second transistor M2 may be turned on to allow the output node Nout to be electrically coupled to the input line 30. That is, when the second transistor M2 is turned on, the waveform of the output signal SSi may correspond to that of the third clock signal CLK3.

The third transistor M3 may be coupled between the first power source VGH and the first node N1. A gate electrode of the third transistor M3 may be coupled to an input terminal I/P to which a start pulse SP or output signal SSi-1 of a previous stage is input. The third transistor M3 may control the voltage level at the first node N1 in response to the start pulse SP or the output signal SSi-1 of the previous stage.

The fourth transistor M4 may be coupled between the first node N1 and a second power source VGL, e.g., a gate low-level voltage source. A gate electrode of the fourth transistor M4 may be coupled to the first input line 10. The fourth transistor M4 may control the voltage level at the first node N1 in response to the first clock signal CLK1 supplied from the first input line 10.

The fifth transistor M5 may be coupled between the second node N2 and the input terminal I/P to which the start pulse SP or output signal SSi-1 of a previous stage is input. A gate electrode of the fifth transistor M5 may be coupled to the second input line 20. The fifth transistor M5 may control the voltage level at the second node N2 in response to the second clock signal CLK2 supplied to the second input line 20.

The first capacitor C1 may be coupled between the second node N2 and the output node Nout. When the voltage level of the third clock signal CLK3 is changed in the state that the second transistor M2 is turned on and the second node N2 is floated, the first capacitor C1 allows the voltage level at the second node N2 to be raised or dropped together due to the coupling operation.

The second capacitor C2 may be coupled between the first power source VGH and the first node N1. That is, the second capacitor C2 may be coupled between the gate and source electrodes of the first transistor M1 so as to stabilize the operation of the first transistor M1.

As described above, according to an embodiment, a shift register with a simple structure may be configured using a relatively small number of devices. Accordingly, the shift register may be easily designed, and a dead space may be reduced.

In an embodiment, the shift register is designed so that a path of leakage current generated through the second node N2 is minimized while a low-level output signal SSi, i.e., a scan signal, is supplied to the output node Nout.

The leakage current may occur due to the off-current of a transistor and the like. If a number of transistors each having a source or drain electrode coupled to the second node N2 is increased, the voltage at the second node N2 may become unstable while a scan signal is output. Therefore, output characteristics of the shift register may be degraded.

Accordingly, in this embodiment, the shift register is designed so that transistors having a source or drain electrode coupled to the second node N2 are minimized, e.g., a single transistor, i.e., the fifth transistor M5, is so coupled. Thus, the output of the shift register may be within a stable range. Accordingly, the path of leakage current generated through the second node N2 may be minimized, and therefore, the output characteristics of the shift register may be stabilized.

Meanwhile, in the stage STi shown in FIG. 3, the first, second and third clock signals CLK1, CLK2, and CLK3 may be supplied to one electrode of the fourth, fifth and second transistors M4, M5, and M2, respectively. However, the first, second and third clock signals CLK1, CLK2, and CLK3 input to each of the stages may be practically supplied by allowing them to be phase-delayed by one clock at every stage.

For example, in the next stage of the stage STi shown in FIG. 3, second, third, and first clock signals CLK2, CLK3, and CLK1 sequentially phase-delayed by one clock may be supplied to one electrodes of the fourth, fifth, and second transistors M4, M5, and M2, respectively.

Hereinafter, the operation of the stage shown in FIG. 3 will be described in detail in conjunction with waveforms of input/output signals shown in FIG. 4. For convenience of illustration, factors such as a threshold voltage of a transistor will not be considered herein.

Referring to FIG. 4, if a low-level first clock signal CLK1 is first supplied to the first input line 10 during a first period t1, the fourth transistor M4 is turned on. Accordingly, a low-level voltage of the second power source VGL is charged at the first node N1.

If the first node N1 is charged with the low-level voltage, the first transistor M1 is turned on. Accordingly, an output signal SSi having a high-level voltage of the first power source VGH is output to the output node Nout.

Meanwhile, the voltage charged in the second node N2 is maintained as a high-level voltage of a previous state during the first period t1.

Thereafter, during a second period t2, a low-level start pulse SP or output signal SSi-1 of a previous stage is input to the input terminal I/P, and a low-level second clock signal CLK2 is input to the second input line 20. Then, the third and fifth transistors M3 and M5 are turned on.

If the third transistor M3 is turned on, the first node N1 is charged with a high-level voltage of the first power source VGH. Accordingly, the first transistor M1 is turned off.

If the fifth transistor is turned on, the low-level start pulse SP or output signal SSi-1 of the previous stage is input to the second node N2, so that the voltage level at the second node N2 is dropped to a low level.

Accordingly, the second transistor M2 is turned on, and the output node Nout is coupled to the third input line 30. However, the voltage level of the third clock signal CLK3 supplied from the third input line 30 is maintained as a high level during the second period t2, and therefore, the voltage level of the output signal SSi is also maintained as a high level. At this time, a voltage at which the second transistor M2 can be turned on is stored in the first capacitor C1.

Thereafter, if the voltage level of the third clock signal CLK3 is transferred to a low level during a third period t3, a low-level voltage lower than the low-level voltage at the second period t2 is charged at the second node N2 due to the coupling operation of a parasitic capacitor (not shown) of the second transistor M2 and the first capacitor C1.

Accordingly, during the third period t3, the second transistor M2 stably maintains a turned-on state, and the low-level voltage of the third clock signal CLK3 is output to the output node Nout. Therefore, a low-level output signal SSi, i.e., a scan signal, is output to the output node Nout during the third period t3.

Thereafter, if the voltage level of the third clock signal CLK3 is again transferred to a high level during a fourth period t4, the voltage level at the second node N2 is raised to a middle level similar or identical to the voltage level at the second period t2 due to the coupling operation of the parasitic capacitor (not shown) of the second transistor M2 and the first capacitor C1.

The voltage level of the third clock signal CLK3 is set as a high level during the fourth period t4. Therefore, a high-level output signal SSi is output to the output node Nout.

In subsequent periods, the start pulse SP or output signal SSi-1 of the previous stage input from the input terminal I/P may be maintained as a high level until a corresponding scan period of the next frame. Therefore, the output signal SSi of the stage STi may also be maintained as a high level.

For example, although a low-level second clock signal CLK2 is input to the second input line 20 during a fifth period t5, the start pulse SP or output signal SSi-1 of the previous stage supplied via the fifth transistor M5 is continuously maintained as a high level. For this reason, the voltage level at the second node N2 is maintained as a high level.

Therefore, although a low-level third clock signal CLK3 is supplied during a sixth period t6, the second transistor M2 may maintain a turned-off state. Accordingly, the output signal SSi of the stage STi may be maintained as a high level regardless of the voltage level of the third clock signal CLK3.

Through the driving described above, each of the stages STi of the shift register according to embodiments may output a scan signal obtained by allowing a start pulse SP or output signal SSi-1 of a previous stage input to each of the stages STi to be phase-delayed by one clock in response to the first to third clock signals CLK1 to CLK3.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A shift register having a plurality of stages coupled to an input line of a start pulse, the shift register being driven by first, second, and third clock signals respectively supplied from first, second, and third input lines, wherein each stage comprises:
a first transistor coupled between a first power source and an output node, the first transistor having a gate electrode coupled to a first node;
a second transistor coupled between the output node and the third input line, the second transistor having a gate electrode coupled to a second node;
a third transistor coupled between the first power source and the first node, the third transistor having a gate electrode coupled to an input terminal to which the start pulse or an output signal of a previous stage is input;
a fourth transistor coupled between the first node and a second power source, the fourth transistor having a gate electrode coupled to the first input line; and
a fifth transistor coupled between the input terminal and the second node, the fifth transistor having a gate electrode coupled to the second input line.

2. The shift register as claimed in claim 1, further comprising a first capacitor coupled between the second node and the output node.

3. The shift register as claimed in claim 1, further comprising a second capacitor coupled between the first power source and the first node.

4. The shift register as claimed in claim 1, wherein the first, second and third clock signals have waveforms whose phases are sequentially delayed.

5. An organic light emitting display device comprising a pixel unit having a plurality of pixels positioned at intersection portions of scan and data lines, a scan driving unit having a shift register configured to sequentially apply scan signals to the scan lines, and a data driving unit configured to apply data signals to the data lines, wherein:
the shift register has a plurality of stages dependently coupled to an input line of a start pulse and is driven by first, second, and third clock signals respectively supplied from first, second, and third input lines; and
each stage includes;
a first transistor coupled between a first power source and an output node, the first transistor having a gate electrode coupled to a first node,
a second transistor coupled between the output node and the third input line, the second transistor having a gate electrode coupled to a second node,
a third transistor coupled between the first power source and the first node, the third transistor having a gate electrode coupled to an input terminal to which the start pulse or an output signal of a previous stage is input,
a fourth transistor coupled between the first node and a second power source, the fourth transistor having a gate electrode coupled to the first input line, and
a fifth transistor coupled between the input terminal and the second node, the fifth transistor having a gate electrode coupled to the second input line.

6. The organic light emitting display device as claimed in claim 5, wherein each stage further comprises:
a first capacitor coupled between the second node and the output node; and
a second capacitor coupled between the first power source and the first node.
